(19) United States
(12) Patent Application Publication
(10) Pub. No.: US 2025/0260379 A1
(43) Pub. Date: Aug. 14, 2025

(54) REDUCING THE EFFECT OF PARASITIC CAPACITANCE IN A HIGH-PASS FILTER EMPLOYED IN PARALLEL WITH ANOTHER FILTER IN A SWITCHING CONFIGURATION

(71) Applicant: Shaoxing Yuanfang Semiconductor Co., Ltd., Shaoxing (CN)

(72) Inventor: Gaurav Agrawal, Bangalore (IN)

(21) Appl. No.: 18/946,904

(22) Filed: Nov. 13, 2024

(30) Foreign Application Priority Data
Feb. 12, 2024 (IN) 202441009293

(51) Int. Cl. H03H 7/01; H03H 7/18; H03H 7/46; H04B 1/04

(52) U.S. Cl. CPC H03H 7/0115; H03H 7/18; H03H 7/463; H04B 1/04

(57) ABSTRACT

Aspects of the present disclosure are directed to a circuit that generates an output signal on an output node from an input signal received on an input node. The circuit contains a first path containing a high-pass filter and a second path containing another filter, both of the first path and the second path being provided in parallel between the input node and the output node. A first switch and a second switch respectively control whether or not the first path and the second path pass the input signal to generate the output signal, where only one of the first switch and the second switch is configured to permit a corresponding path to pass the input signal at any specific time. The high-pass filter contains a first capacitor and a first inductor, with the first switch being coupled between the first capacitor and the first inductor in the first path.

### PRIORITY CLAIM

The instant patent application is related to and claims priority from the co-pending India provisional patent application entitled, “Improving S11 and Phase Flatness in Phase Shifters”, Serial No.: 202441009293, Filed: 12 Feb. 2024, Attorney docket no.: AURA-356-INPR, which is incorporated in its entirety herewith to the extent not inconsistent with the description herein.

### BACKGROUND

Technical Field

Embodiments of the present disclosure relate generally to high-pass filters, and more specifically to reducing the effect of parasitic capacitance in a high-pass filter employed in parallel with another filter in a switching configuration.

### Related Art

A high-pass filter is a circuit that operates to ‘pass through’ input signals with a frequency above a certain frequency, referred to as the cut-off frequency, while blocking (attenuating) input signals with other frequencies. High-pass filters often find use in audio and image processing applications, amplifiers, phase shifters, etc. as is well known in the relevant arts.

In certain applications, high-pass filters are employed in a switching configuration in parallel with another filter such that the path of an input signal is through the high-pass filter or the other filter. Thus, the input signals may be passed through the high-pass filter in some durations, while being passed through the parallel path in other (non-overlapping) durations.

A high-pass filter is often associated with parasitic capacitance(s) that are not intended to be present, and lead to changes in the output signal from the desired value. Therefore, it is desirable to reduce the effect of such parasitic capacitance(s).

Aspects of the present disclosure are directed to reducing the effect of parasitic capacitance in a high-pass filter employed in parallel with another filter in a switching configuration.

### BRIEF DESCRIPTION OF THE VIEWS OF DRAWINGS

Example embodiments of the present disclosure will be described with reference to the accompanying drawings briefly described below.

FIG. 1 is a block diagram of an example device in which several aspects of the present disclosure can be implemented.

FIG. 2 is a diagram illustrating the implementation of a section of a phase shifter in an embodiment of the present disclosure.

FIG. 3A is a diagram illustrating the implementation of a section of a phase shifter in another embodiment of the present disclosure.

FIG. 3B is a diagram illustrating the implementation of a compensation network of a section of a phase shifter in an embodiment of the present disclosure.

FIG. 4 is a block diagram illustrating the implementation of the section of a phase shifter according to a prior technique.

FIG. 5 is a block diagram illustrating the implementation of a high-pass filter bank, in an embodiment of the present disclosure.

FIG. 6 is a block diagram of a system in which a device implemented according to several aspects of the present disclosure can be incorporated, in an embodiment of the present disclosure.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

Aspects of the present disclosure are directed to a circuit that generates an output signal on an output node from an input signal received on an input node. The circuit contains a first path that contains a high-pass filter and a second path that contains another filter, both of the first path and the second path being provided in parallel between the input node and the output node. A first switch and a second switch respectively control whether or not the first path and the second path pass the input signal to generate the output signal, where only one of the first switch and the second switch is configured to permit a corresponding path to pass the input signal at any specific time. The high-pass filter contains a first capacitor and a first inductor, with the first switch being coupled between the first capacitor and the first inductor in the first path.

By having the first switch after the first capacitor, the effect of any parasitic capacitance associated with the first capacitor is reduced.

According to another aspect of the present disclosure, the first path contains a third switch and the second path contains a fourth switch, with the third switch being coupled between the first inductor and the output node. The other filter is coupled between the second switch and the fourth switch, with the fourth switch being coupled between the other filter and the output node.

In an embodiment, the other filter is a low-pass filter as a part of a phase shifter. In another embodiment, the other filter is a high-pass filter as a part of a high-pass filter bank.

According to another aspect of the present disclosure, a first compensation inductor is coupled to the input node common to the first path and the second path. The first compensation inductor has a first inductance to minimize the effect of a first parasitic capacitance associated with the first capacitor on one or more characteristics of the high-pass filter, wherein the first parasitic capacitance manifests between the input node and a first constant reference potential, and wherein the first compensation inductor is in series configuration with the first capacitor

In an embodiment, a first routing wire is coupled between the input node and the first compensation inductor, with the first routing wire having a first additional inductance to further minimize the effect of the first parasitic capacitance.

According to another aspect of the present disclosure, the first switch and the third switch are operable to be closed when a first logic signal is in a first state (e.g., logic high), and to be open when the first logic signal is in a second state (e.g., logic low). The second switch and the fourth switch are operable to be closed when the first logic signal is in the second state, and to be open when the first logic signal is in the first state.

Several aspects of the present disclosure are described below with reference to examples for illustration. However, one skilled in the relevant art will recognize that the disclosure can be practiced without one or more of the specific details or with other methods, components, materials and so forth. In other instances, well known structures, materials, or operations are not shown in detail to avoid obscuring the features of the disclosure. Furthermore, the features/aspects described can be practiced in various combinations, though only some of the combinations are described herein for conciseness.

### 2. Example Device

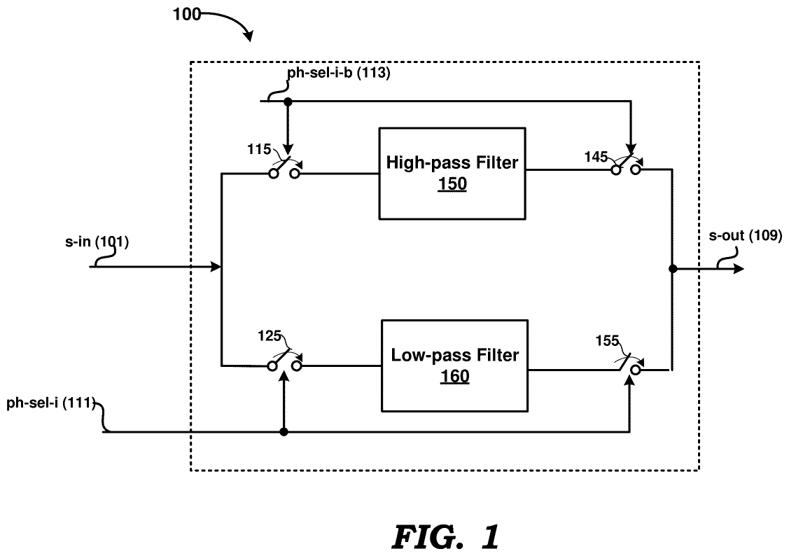

FIG. 1 is a block diagram depicting a logical view of a section of an example device in which several aspects of the present disclosure can be implemented. FIG. 1 depicts section 100 of a phase shifter implemented according to aspects of the present disclosure. Section 100 is shown connected to receive input signal s-in on path 101 and to generate output signal s-out on path 109. Section 100 is shown containing switches 115, 125, 145 and 155, high-pass filter 150 and low-pass filter 160.

In an embodiment, signal s-in (101) represents a radio-frequency signal, generally a sinusoidal wave, with a fixed frequency. The frequency of signal s-in (101) may be in a range suitable for the desired application, as is well known in the relevant arts.

High-pass filter (HPF) 150 receives signal s-in on path 101 and performs high-pass filtering of the signal and forwards a filtered signal on path 109. High-pass filtering refers to a filtering operation by which frequency components in a signal (here, input signal s-in 101) with a frequency higher than a selected cut-off frequency are passed, while those with frequencies lower than the cut-off are attenuated or “cut-off”. HPF may be implemented in a known manner.

Low-pass filter (LPF) 160 receives signal s-in on path 101 and performs low-pass filtering of the signal and forwards a filtered signal on path 109. Low-pass filtering refers to a filtering operation by which frequency components in a signal (here, input signal s-in 101) with a frequency lower than a selected cut-off frequency are passed, while those with frequencies higher than the cut-off are attenuated or “cut-off”. LPF may be implemented in a known manner.

Switches 115 and 145, under the control of bit ph-sel-1 (111), are operable to select or de-select HPF 150 to provide output signal s-out (109). Switches 125 and 155, under the control of bit ph-sel-i-b (113), are operable to select or de-select LPF 160 to provide output signal s-out (109). In an embodiment, switches 115, 125, 145 and 155 are implemented as single-pole single-throw CMOS (complementary metal-oxide semiconductor) switches. However, in alternative embodiments, switches 115, 125, 145 and 155 may be implemented using other technologies, as will be apparent to a skilled practitioner. When switches 115 and 145 are closed, signal s-in (101) flows on path containing HPF 150. On the other hand, when switches 125 and 155 are closed, signal s-in (101) flows on path containing LPF 160.

Thus, section 100 may be viewed as containing two paths provided in parallel between input node (101) and output node (109)-a high-pass path containing HPF 150 and a low-pass path containing LPF 160. Control bits ph-sel-i (111) (and ph-sel-i-b, 113) respectively control the closing and opening of switches 115/145 (and 125/155) such that only one corresponding path is permitted to pass input signal s-in (101) at any specific time. In other words, in a duration when switches 125 and 155 are closed under the control of bit ph-sel-i 111, signal s-in (101) passes through LPF 160. In the same duration, switches 115 and 145 are open (under the control of bit ph-sel-i-b 113, which is complement of signal ph-sel-i 111) such that signal s-in (101) does not pass through HPF 150.

Signal output by HPF 150/LPF 160 is shifted in phase with respect to input signal, s-in (101), as is well known in the relevant arts. The amplitude of output signal s-out (109) however is substantially equal to that of input signal s-in (101). Phase shift in output signal occurs due to presence of reactive elements (capacitors and/or inductors) in the filters, as is also well known in the relevant arts. A HPF provides a positive phase shift, i.e., phase of the output signal advances with respect to that of the input signal, while a LPF provides a negative phase shift, i.e., phase of the output signal lags with respect to the phase of the input signal.

Each of HPF 150 and LPF 160 is designed to provide a corresponding pre-determined phase-shift around a certain center frequency. A desired phase-shift in an output signal is achieved by switching between HPF 150 and LPF 160.

Section 100 is part of a phase shifter (not shown) that is operable to provide desired values of phase shifts around the center frequency. The operation of section 100 is controlled by 1 bit (signal 111). Thus, in a 4-bit phase shifter, for example, four sections similar to the one depicted in Figure I would be cascaded in series, although each section will have a corresponding HPF and LPF designed to provide a respective pre-determined phase shift. Each of the sections will be controlled individually by a respective control bit (generated by a control block not shown in FIG. 1). Thus, 16 possible values of phase shifts may be obtained under the control of 4 bits in the 4-bit phase shifter. As an example, the four sections of the 4-bit phase shifter may provide corresponding phase shifts of 180 degrees, 90 degrees, 45 degrees and 22.5 degrees. One of the HPF or LPF paths is considered as providing a reference phase shift, while the other path provides the desired phase shift with respect to the reference phase shift value. Such a switched arrangement for obtaining a desired range of phase shifts is employed for improved phase flatness and improved impedance matching over a large bandwidth. Phase flatness refers to be the ability of a device to provide a flat phase shift (minimum phase error/deviation from expected phase shift value) over frequency, as is well known in the relevant arts.

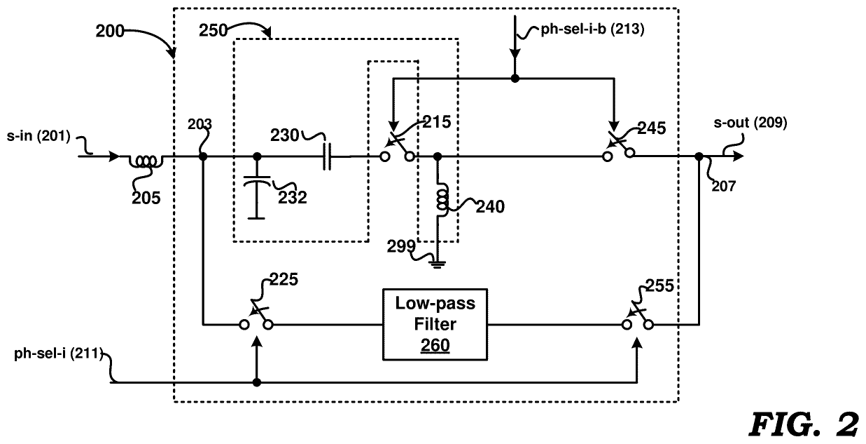

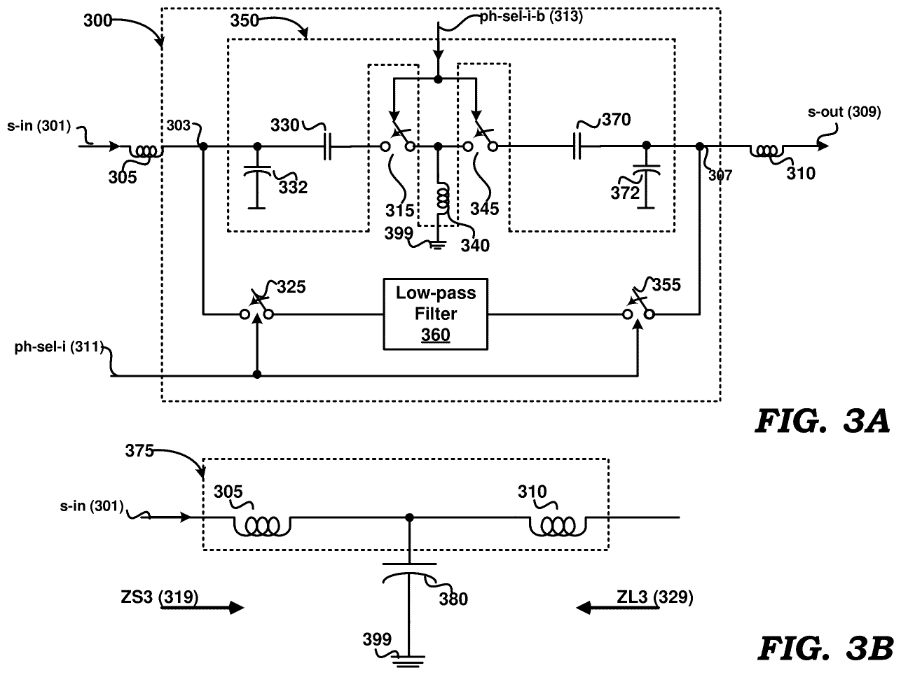

Parasitic capacitances present in the HPF and/or LPF may lead to deviation in the output signal from the desired value. Aspects of the present disclosure operate to reduce the effect of such parasitic capacitances, as described in detail with respect to FIGS. 2 and 3A-3B.

### 3. Example Implementation of a Section Containing Second-Order High-Pass Filter

FIG. 2 is a diagram illustrating the implementation details of a section (200) of a phase shifter in an embodiment of the present disclosure. FIG. 2 is shown as containing compensation inductor 205, HPF 250, LPF 260 and switches 215, 225, 245 and 255. Switches 215, 225, 245 and 255, and signals 201, 209, 211 and 213 respectively correspond to switches 115, 125, 145 and 155, and signals 101, 109, 111 and 113 in FIG. 1, and their description is not repeated here in the interest of conciseness. Node 299 represents ground.

HPF 250 is a second-order filter and is shown as containing series capacitor 230 and shunt inductor 240. Also shown in FIG. 2 is parasitic capacitance 232 associated with capacitor 230. In an embodiment, capacitor 230 is implemented as metal-insulator-metal (MIM) or metal-oxide-metal (MOM) capacitor. Parasitic capacitance 232 represents, for example, bottom plate capacitance associated with capacitor 230, as is well known in the relevant arts. The value of parasitic capacitance 232 may be around 1-5% of the capacitance value of capacitor 230. Thus, the absolute value of parasitic capacitance 232 value increases when the capacitance value of capacitor 230 increases. Capacitor 230 may have large values in HPF 250 providing small phase shifts. For example, capacitor 230 may have a value of the order of tens of pico-Farads at a center frequency of around 2 GHz for HPF 250 providing 11.25 degrees phase shift.

Switch 215 is placed after (in the signal path from path 201 to path 209) capacitor 230, i.e., coupled between series capacitor 230 and shunt inductor 240. By placing switch 215 after capacitor 230 instead of before (to the left of) capacitor 230, it may be appreciated that the effect of parasitic capacitance 232 is manifested at node 203 which is common to both high-pass and low-pass paths. An advantage of making parasitic capacitance(s) common to both high-pass and low-pass filter paths is that the mismatch in impedance matching due to parasitic capacitance 232 may be reduced by employing a suitable matching network (such as compensation inductor 205) that cancels or offsets the effect of parasitic capacitance 232. An example third-order HPF and corresponding matching network are described next.

### 4. Example Implementation of a Section Containing a Third-Order High-Pass filter

FIG. 3A is a diagram illustrating the implementation details of a section (300) of a phase shifter in an embodiment of the present disclosure. FIG. 3A is shown as containing compensation inductors 305 and 310, HPF 350, LPF 360 and switches 315, 325, 345 and 355. Switches 315, 325, 345 and 355, and signals 301, 309, 311 and 313 respectively correspond to switches 115, 125, 145 and 155, and signals 101, 109, 111 and 113 in FIG. 1, and their description is not repeated here in the interest of conciseness. Node 399 represents ground. HPF 350 is a third-order filter and is shown as containing series capacitors 330 and 370, and shunt inductor 340. Also shown in FIG. 3A are parasitic capacitances 332 and 372 respectively associated with capacitors 330 and 370.

Switch 315 is placed after series capacitor 330, and switch 345 is placed before series capacitor 370 in the signal path. As noted with respect to FIG. 2, due to such placement of switches 315 and 345 relative to capacitors 330 and 370, parasitic capacitances 332 and 372 are in the path common to both high-pass and low-pass filters. The effect of parasitic capacitances 332 and 372 may be reduced by employing a matching network that cancels or offsets the effect of parasitic capacitances 332 and 373.

An example matching network is shown in FIG. 3B. Matching T-network 375 is shown containing compensation inductors 305 and 310. Capacitor 380 has a capacitance magnitude equivalent to that of combined parasitic capacitances 332 and 372. The inductance values of compensation inductors 305 and 310 may be calculated in a known manner for a desired source impedance ZS3 (319) and a desired load impedance ZL3 (329) (ZS3 and ZL3 values being typically 50 Ohms or 75 Ohms for radio frequency applications).

A part of the inductance value of compensation inductors 305 and 310 may be obtained from the connecting wire itself (used for routing signals between adjacent sections of the phase shifter) in the layout, and any required additional inductance value may be provided by employing an explicit inductor. Such apportioning of inductance values between routing and external component may be determined based on simulation results during routing phase.

Although the illustrative embodiments of FIGS. 2 and 3A respectively depict second-order and third-order HPFs, aspects of the present disclosure can be equally well applied to higher order HPFs with corresponding changes to positions of switches (that enable the high-pass path) in all or selected sections of a phase shifter, as will be apparent to a skilled practitioner by reading the disclosure herein.

Although the matching T-network 375 is shown as containing series inductor(s) and shunt capacitance, matching networks may be implemented differently in alternative embodiments (such as other types of L-sections or L-networks, depending on considerations such as type of frequency response, bandwidth, case of implementation, etc.) as will be apparent to a skilled practitioner.

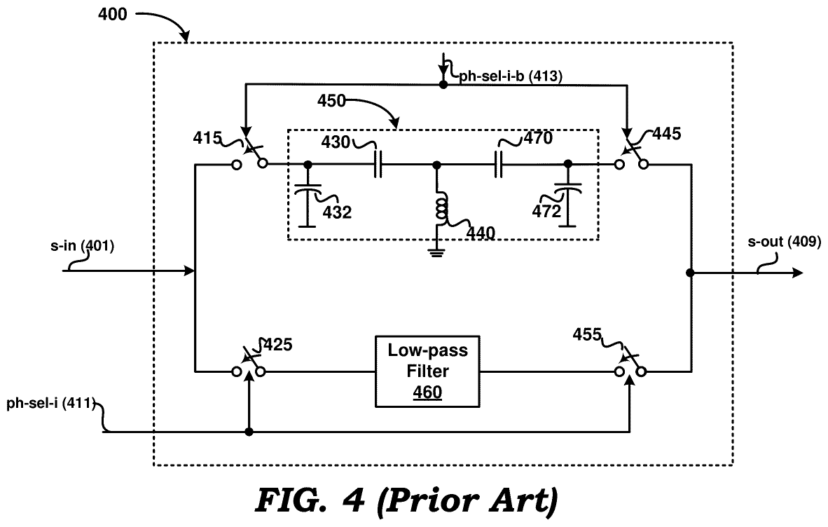

Several features and advantages of the present disclosure would be better understood and appreciated when compared with conventional phase shifters. Accordingly, an example prior phase shifter is briefly described next with respect to FIG. 4.

### 5. Section of a Prior Phase Shifter

FIG. 4 shows section 400 of a prior phase shifter that contains third-order HPF 450, LPF 460, switches 415, 425, 445 and 455, and parasitic capacitances 432 and 472. Switch 415 is shown connected before series capacitor 430 and switch 445 is shown connected after series capacitor 470 in prior section 400.

It may be appreciated that due to the positions of switches 415 and 445 in prior section 400, parasitic capacitances 432 and 472 are present only in high-pass path (containing HPF 450), i.e., only when switches 415 and 445 are closed. The effect of parasitic capacitances 432 and 472 is not manifested when switches 425 and 455 are closed (i.e., when signal 401 flows through LPF 460). In other words, parasitic capacitances 432 and 472 are not in the path common to both HPF and LPF, and accordingly their effect cannot be cancelled/offset using a common matching network.

Parasitic capacitances 432 and 472 negatively impact the operation of phase shifter 400 at least in terms of phase flatness and impedance matching. Specifically, when high-pass path is enabled, parasitic capacitances 432 and 472 behave as low-pass networks, thus altering both absolute value and slope of phase shift. Consequently, phase flatness with respect to frequency is limited. In addition, HPF 450 (and LPF 460) are designed to provide a particular impedance match in a certain frequency range. Presence of parasitic capacitances 432 and 472 changes the matched impedance, and consequently leads to increased value of reflection co-efficient (S11 parameter). Even if shunt inductor (440) value were to be adjusted or matching networks were to be added for each HPF to cancel the effect of parasitic capacitance(s) and to reduce reflection co-efficient, such cancellation would hold good only at one frequency. Therefore, such a solution would, in turn, affect phase flatness with respect to frequency.

By interchanging the position of switches and series capacitors (as depicted in FIGS. 2 and 3A), the parasitic capacitance(s) are brought to a path common to HPF and LPF. Since the value of parasitic capacitances can be estimated from the designed values of series capacitors in HPF in each section of the phase shifter, a matching network may be designed to offset or cancel the effect of parasitic capacitances on impedance matching.

The description is continued to illustrate example implementation of another circuit in which interchanging the switch positions (with respect to series capacitors in HPFs) reduces the effect of parasitic capacitances.

### 6. Example Implementation of a High-Pass Filter Bank

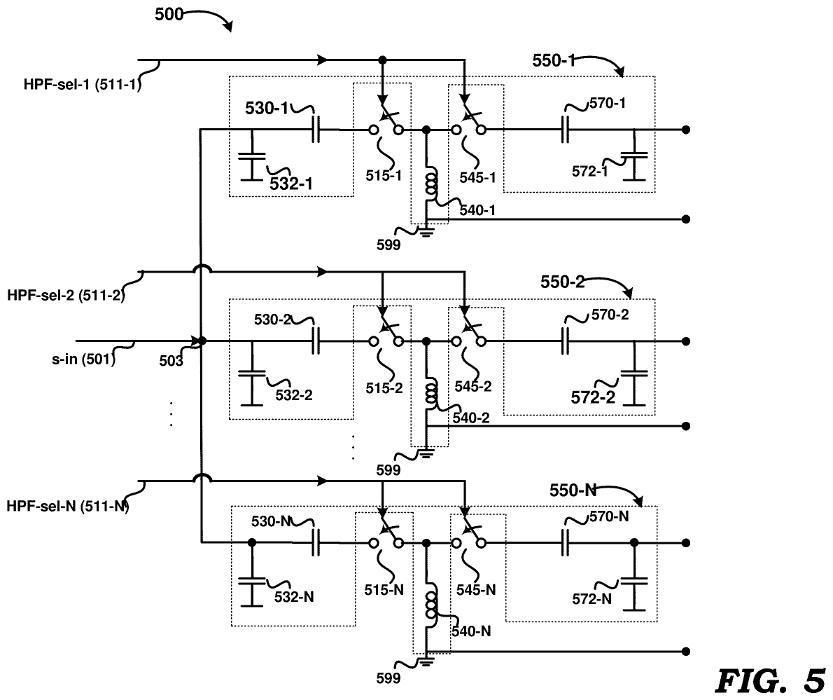

FIG. 5 is a diagram illustrating the implementation details of a high-pass filter bank in an embodiment of the present disclosure. Filter bank 500 is shown containing HPFs 550-1 through 550-N, and switches 515-1 through 515-N and 545-1 through 545-N.

HPFs 550-1 through 550-N may be collectively or individually referred to below by respective numeral 550, as will be clear from the context. Also, switches 515-1 through 515-N, and 545-1 through 545-N may be collectively or individually referred to by respective numerals 550, 515 and 545, as will also be clear from the context. Similar convention is followed for other blocks/components/signals throughout the disclosure.

Each HPF 550 is shown implemented as a third-order HPF containing series capacitors 530 and 570 and shunt inductor 540. Also shown in FIG. 5 are parasitic capacitances 532 and 572 associated respectively with capacitors 530 and 570. It is noted herein that only components as relevant to the understanding of the disclosure are depicted in FIG. 5. It is understood that filter bank 500 can contain more or fewer blocks than those shown in FIG. 5. Although the illustrative embodiment depicts third-order HPFs, aspects of the present disclosure are equally applicable to HPFs of higher orders with suitable modifications to the circuitry, as will be apparent to a skilled practitioner by reading the disclosure herein.

Each HPF 550 receives signal s-in on path 501 and performs high-pass filtering of the signal and forwards a filtered signal on path 509. Each pair of switches 515 and 545 is operable to select or de-select corresponding HPF 550 to provide output signal s-out (509) under the control of respective HPF-sel-bit (511).

Switches 515-1/545-1 through 515-N/545-N are operable to permit input signal s-in (501) through the corresponding HPF 550 in non-overlapping durations. Thus, when switches 515-1 and 545-1 are closed, signal s-in (501) flows only on path containing HPF 550-1. When switches 515-2 and 545-2 are closed, signal s-in (501) flows only on path containing HPF 550-2. In an embodiment, switches 515-1/545-1 through 515-N/545-N are implemented as CMOS switches. However, in alternative embodiments, switches 515-1/545-1 through 515-N/545-N may be implemented differently, as will be apparent to a skilled practitioner.

Control bits 511-1 (HPF-scl-1) through 511-N (HPF-sel-N) control the closing and opening of switches 515 and 545 such that only one corresponding HPF/path is permitted to pass input signal s-in (501) at any specific time. Control bits 511 may be generated by a control block not shown in FIG. 5.

In each path, switch 515 is placed after corresponding series capacitor 530 (i.e., coupled between capacitor 530 and inductor 540), and switch 545 is placed before corresponding series capacitor 570 (i.e., coupled between inductor 540 and capacitor 570). Due to such arrangement of switches, it may be appreciated that the effect of parasitic capacitances 532 and 572 is manifested at node 503 which is common to all paths. Accordingly, the mismatch in impedance matching due to parasitic capacitances 532 and 572 may be reduced by employing a matching network that cancels or offsets the effect of (equivalent) parasitic capacitances 532 and 572 in a manner similar to that described with respect to FIGS. 2 and 3A.

Although, the description above is provided in the context of a phase shifter (FIGS. 2 and 3A-3B) and a high-pass filter bank (FIG. 5), several aspects of the present disclosure are in general applicable to implementations of networks in which a HPF is coupled in parallel with another filter with a corresponding switching arrangement to select either one of the HPF and the other filter to pass an input signal.

Thus, aspects of the present disclosure reduce the effect of parasitic capacitance in a HPF employed in parallel with another filter in a switching configuration. Sections 200 and 300 of phase shifters implemented as described above can be incorporated in a larger device or system as described briefly next.

### 7. Device/System

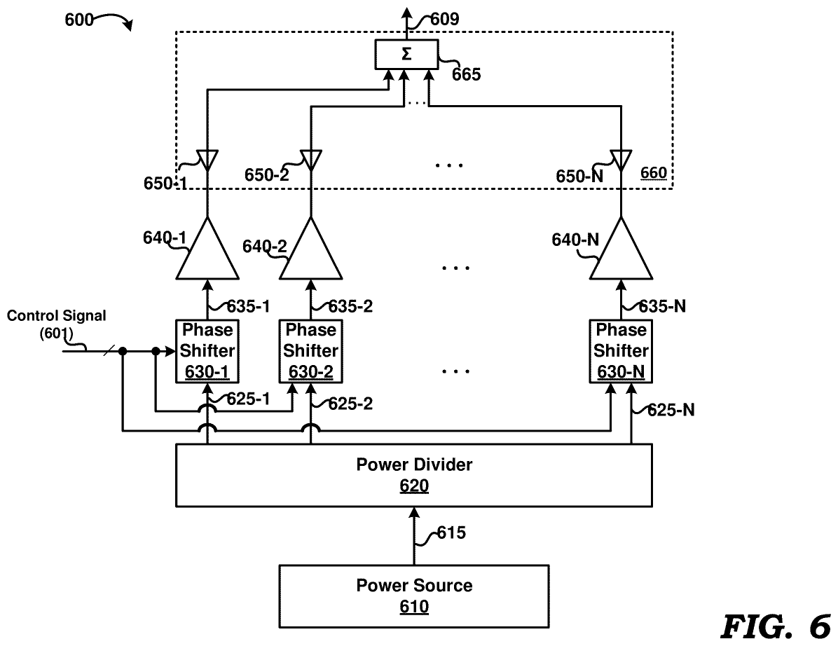

FIG. 6 is a block diagram illustrating the implementation details of a device/system incorporating section 200/300 described in detail above, in an embodiment of the present disclosure. Beam-forming circuit 600 is shown containing power source 610, power divider 620, phase shifters 630-1 to 630-N, amplifiers 640-1 to 640-N, antenna 660 containing antenna elements 650-1 to 650-N and combiner 665. The specific components/blocks of beam-forming circuit 600 are shown merely by way of illustration. However, beam-forming circuit 600 may contain more or fewer components/blocks. Beam-forming circuit 600 may be part of a larger device/system, such as user equipment (UE) or gNBs in communication systems, network relays, radar and sonar systems, etc.

Power source 610 represents a radio-frequency (RF) signal generator that generates RF signals 615 with a desired set of characteristics such as frequency, amplitude, phase, etc.

Power divider 620 splits RF signal 615 into multiple signals 625-1 through 625-N, which are equal in amplitude and phase, and have power that is a fraction of power of signal 615.

Each phase shifter 630 receives a corresponding signal 625 and generates respective phase-shifted signal 635. The amount of phase-shift value to be provided by each phase shifter 620 may be specified by control bits of control signal 601. One or more sections of phase shifter 630 is/are implemented as section 200/300 described in detail above.

Each amplifier 640 receives a corresponding phase-shifted signal 635, amplifies the phase-shifted signal, and forwards the amplified phase-shifted signal to a respective antenna clement 650.

Each antenna clement 650 receives a corresponding amplified phase-shifted signal 635, and signals generated by collection of antenna elements 650-1 to 650-N are assembled together by combiner 665 such that the radiation pattern of each individual element 650 constructively combines with that of neighboring antenna element(s) to form the desired radiation pattern. Thus, beam-forming circuit 600 operates to steer signal 609 radiated by antenna 660 in a desired direction. The desired direction is controlled by control signal 601 noted above.

Thus, aspects of the present disclosure reduce the effect of parasitic capacitance in a high-pass filter employed in parallel with another filter in a switching configuration.

### 8. Conclusion

References throughout this specification to “one embodiment”, “an embodiment”, or similar language means that a particular feature, structure, or characteristic described in connection with the embodiment is included in at least one embodiment of the present disclosure. Thus, appearances of the phrases “in one embodiment”, “in an embodiment” and similar language throughout this specification may, but do not necessarily, all refer to the same embodiment.

While in the illustrations of FIGS. 1, 2, 3A, 5 and 6, although terminals/nodes are shown with direct connections to (i.e., “connected to”) various other terminals, it should be appreciated that additional components (as suited for the specific environment) may also be present in the path, and accordingly the connections may be viewed as being “electrically coupled” to the same connected terminals.

In the instant application, the power and ground terminals are referred to as constant reference potentials.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

What is claimed is:

1. A circuit to generate an output signal on an output node from an input signal received on an input node, said circuit comprising:
a first path comprising a high-pass filter and a second path comprising another filter, both of said first path and said second path being provided in parallel between said input node and said output node; and
a first switch and a second switch respectively controlling whether or not said first path and said second path pass said input signal to generate said output signal, wherein only one of said first switch and said second switch is configured to permit a corresponding path to pass said input signal at any specific time,
wherein said high-pass filter comprises a first capacitor and a first inductor,
wherein said first switch is coupled between said first capacitor and said first inductor in said first path.

2. The circuit of claim 1, wherein said first path comprises a third switch and said second path comprises a fourth switch, wherein said third switch is coupled between said first inductor and said output node,
wherein said another filter is coupled between said second switch and said fourth switch, wherein said fourth switch is coupled between said another filter and said output node.

3. The circuit of claim 1, wherein said another filter is a low-pass filter.

4. The circuit of claim 1, wherein said another filter is another high-pass filter.

5. The circuit of claim 2, wherein a first compensation inductor is coupled to said input node common to said first path and said second path,
said first compensation inductor having a first inductance to minimize the effect of a first parasitic capacitance associated with said first capacitor on one or more characteristics of said high-pass filter, wherein said first parasitic capacitance manifests between said input node and a first constant reference potential, and wherein said first compensation inductor is in series configuration with said first capacitor.

6. The circuit of claim 5, wherein a first routing wire is coupled between said input node and said first compensation inductor, said first routing wire having a first additional inductance to further minimize said effect of said first parasitic capacitance.

7. The circuit of claim 3, wherein said first switch and said third switch are operable to be closed when a first logic signal is in a first state, and to be open when said first logic signal is in a second state,
wherein said second switch and said fourth switch are operable to be closed when said first logic signal is in said second state, and to be open when said first logic signal is in said first state.

8. The circuit of claim 2, wherein said high-pass filter comprises a second capacitor, wherein said third switch is coupled between said first inductor and said second capacitor, wherein said second capacitor is coupled between said third switch and said output node.

9. The circuit of claim 8, wherein a second compensation inductor is coupled to said output node common to said first path and said second path,
said second compensation inductor having a second inductance to minimize the effect of a second parasitic capacitance associated with said second capacitor on said one or more characteristics of said high-pass filter, wherein said second parasitic capacitance manifests between said output node and said first constant reference potential, and wherein said second compensation inductor is in series configuration with said second capacitor.

10. The circuit of claim 9, wherein a second routing wire is coupled between said output node and said second compensation inductor, said second routing wire having a second additional inductance to further minimize said effect of said second parasitic capacitance.

11. The circuit of claim 8, wherein magnitudes of inductance of said first inductor and respective capacitances of said first capacitor and said second capacitor are implemented to obtain desired values of said one or more characteristics of said high-pass filter,
wherein a first one of said first path and said second path provides a reference phase shift between said input node and said output node, wherein a second one of said first path and said second path provides a desired phase shift between said input node and said output node with respect to said reference phase shift.

12. The circuit of claim 8, wherein said circuit is comprised in a phase shifter.

13. A phase shifter coupled to receive an input signal on an input node, and to generate a phase-shifted signal on an output node, wherein said phase shifter comprises:
a plurality of sections connected in series such that a section-output-signal generated by a section of said plurality of sections on a corresponding section-output node is provided as a section-input-signal to a next section of said plurality of sections on a corresponding section-input node,
wherein a first section of said plurality of sections is coupled to receive said input signal on said corresponding section-input node, wherein a last section of said plurality of sections is coupled to generate said phase-shifted signal on said corresponding section-output node,
wherein each section of said plurality of sections comprises:
a first inductor, a first capacitor, a first switch, a second inductor, and a second switch in a first path between said section-input node and said section-output node, wherein said first capacitor and said second inductor form a high-pass filter; and
a third switch, a second filter, a fourth switch in a second path between said section-input node and said section-output node,
wherein a first terminal of said first inductor is coupled to said section-input node to receive said section-input-signal,
wherein a second terminal of said first inductor is coupled to a first terminal of said first capacitor at a first node,
wherein first switch is coupled between a second terminal of said first capacitor and a second node,
wherein said second inductor is coupled between said second node and a constant reference potential,
wherein said second switch is coupled between said second node and said section-output node,
wherein said third switch is coupled between said first node and said second filter,
wherein said fourth switch is coupled between said second filter and said section-output node.

14. The phase shifter of claim 13, wherein said each section comprises:
a second capacitor; and
a third inductor,
wherein said second capacitor is coupled between said second switch and said section-output node,
wherein said third inductor is coupled to said section-output node in series configuration with said second capacitor.

15. A system comprising:
a power source to receive an input voltage and to generate a radio-frequency (RF) signal;
a power divider coupled to receive said RF signal from said power source, and to generate a plurality of divided signals with each divided signal having a portion of a power of said RF signal, and having equal amplitude and phase;
a plurality of phase shifters with each phase shifter coupled to receive a respective signal of said plurality of divided signals on corresponding input node and a control signal, and to generate a respective phase-shifted signal on a corresponding output node;
a plurality of power amplifiers with each power amplifier coupled to receive a corresponding phase-shifted signal of said plurality of phase-shifted signals and to generate a respective amplified signal;
an antenna comprising a combiner and plurality of antenna elements with each antenna element coupled to receive a corresponding amplified signal, wherein said combiner combines said plurality of amplified signals to generate a single transmit signal,
wherein each phase shifter of said plurality of phase shifters comprises a corresponding plurality of sections connected in series, wherein a first section of said plurality of sections is coupled to receive a corresponding one of said plurality of divided signals, wherein a last section of said plurality of sections is coupled to generate a corresponding one of said plurality of phase-shifted signals, wherein each section of said plurality of sections comprises:
a first path comprising a high-pass filter and a second path comprising another filter, both of said first path and said second path being provided in parallel between said input node and said output node; and
a first switch and a second switch respectively controlling whether or not said first path and said second path pass said input signal to generate said output signal, wherein only one of said first switch and said second switch is configured to permit a corresponding path to pass said input signal at any specific time,
wherein said high-pass filter comprises a first capacitor and a first inductor,
wherein said first switch coupled between said first capacitor and said first inductor in said first path.

16. The system of claim 15, wherein said first path comprises a third switch and said second path comprises a fourth switch, wherein said third switch is coupled between said first inductor and said output node,
wherein said another filter is coupled between said second switch and said fourth switch, wherein said fourth switch is coupled between said another filter and said output node.

17. The system of claim 15, wherein said another filter is a low-pass filter.

18. The system of claim 15, wherein said another filter is another high-pass filter.

19. The system of claim 16, wherein a first compensation inductor is coupled to said input node common to said first path and said second path,
said first compensation inductor having a first inductance to minimize the effect of a first parasitic capacitance associated with said first capacitor on one or more characteristics of said high-pass filter, wherein said first parasitic capacitance manifests between said input node and a first constant reference potential, and wherein said first compensation inductor is in series configuration with said first capacitor,
wherein a first routing wire is coupled between said input node and said first compensation inductor, said first routing wire having a first additional inductance to further minimize said effect of said first parasitic capacitance.

20. The system of claim 16, wherein said high-pass filter comprises a second capacitor, wherein said third switch is coupled between said first inductor and said second capacitor, wherein said second capacitor is coupled between said third switch and said output node,
wherein a second compensation inductor is coupled to said output node common to said first path and said second path,
said second compensation inductor having a second inductance to minimize the effect of a second parasitic capacitance associated with said second capacitor on said one or more characteristics of said high-pass filter, wherein said second parasitic capacitance manifests between said output node and said first constant reference potential, and wherein said second compensation inductor is in series configuration with said second capacitor.
